(19) United States
(12) Patent Application Publication
(10) Pub. No.: US 2012/0111029 A1
(43) Pub. Date: May 10, 2012

(54) AC POWERED THERMOELECTRIC DEVICE

(75) Inventors: Yong-Il KWON, Gyeonggi-do (KR); Su Bong Jang, Gyeonggi-do (KR)

(73) Assignee: SAMSUNG ELECTRO-MECHANICS CO., LTD.

(21) Appl. No.: 13/071,150

(22) Filed: Mar. 24, 2011

(30) Foreign Application Priority Data
Nov. 5, 2010 (KR) 10-2010-0109946

(51) Int. Cl. F25B 21/02; H01L 35/28

(52) U.S. Cl. 62/3.7; 136/203

(57) ABSTRACT

Disclosed herein is an AC powered thermoelectric device, including: a power supplier outputting AC power; a plurality of thermoelectric modules; and a plurality of rectifiers connected to each of the plurality of thermoelectric modules in series and applying the AC power having different polarities to each of the plurality of thermoelectric modules, whereby the positions of the hot side and the cold side are fixed to function as a heater and a cooler, while using the AC power.

### CROSS REFERENCE(S) TO RELATED APPLICATIONS

This application claims the benefit under 35 U.S.C. Section [120, 119, 119(e)] of Korean Patent Application No. 10-2010-0109946, entitled “AC Powered Thermoelectric Device” filed on Nov. 5, 2010, which is hereby incorporated by reference in its entirety into this application.

### BACKGROUND OF THE INVENTION

1. Technical Field

The present invention relates to a thermoelectric device, and more particularly, to an AC powered thermoelectric device capable of functioning as a heater and a cooler, while using AC power by connecting diodes to each of a plurality of thermoelectric modules.

2. Description of the Related Art

Due to the increase in use of fossil energy that causes global warming and exhausts energy resources, more research into thermoelectric devices capable of efficiently using energy has recently been conducted.

A thermoelectric device may be used as a power generator using a Seebeck effect where electromotive force is generated when both ends of the thermoelectric element have a difference in temperature or a heater or a cooler using a Peltier effect where one end of the thermoelectric device radiates heat and the other end thereof absorbs heat when power is applied to the thermoelectric device.

In the case of the heater and the cooler using the Peltier effect, a hot side and a cold side are changed according to a direction of current applied to the thermoelectric device, such that DC power is required.

In other words, when AC power is used, the direction of current applied to the thermoelectric device is frequently changed and thus the hot side and the cold side are also frequently changed, and as a result, it is impossible to function as a heater and a cooler.

Therefore, in order to use AC power instead of the DC power, an AC-DC converter converting AC power to DC power is installed on the thermoelectric device; however, problems arise in that a system implementing the thermoelectric device is complicated and the manufacturing cost thereof is increased.

### SUMMARY OF THE INVENTION

An object of the present invention is to provide an AC powered thermoelectric device capable of functioning as a heater and a cooler by fixing the positions of a hot side and a cold side by connecting diodes to each of the plurality of thermoelectric modules in each different direction, while using AC power.

According to an exemplary embodiment of the present invention, there is provided an AC powered thermoelectric device, including: a power supplier outputting AC power; a plurality of thermoelectric modules; and a plurality of rectifiers connected to each of the plurality of thermoelectric modules in series and applying the AC power having different polarities to each of the plurality of thermoelectric modules.

The plurality of rectifiers may allow some of the plurality of thermoelectric modules to be operated when positive AC power is applied from the power supplier, and allow the remainder of the plurality of thermoelectric modules to be operated when negative AC power is applied from the power supplier.

The plurality of rectifiers may be connected in parallel, having different polarities.

The rectifiers may be diodes.

The plurality of thermoelectric modules may be connected to each other in parallel.

In addition, each of the plurality of thermoelectric modules may include: first and second substrates; first and second electrodes each disposed on the inner surface of the first and second substrates; and thermoelectric elements provided between the first and second electrodes to be bonded to the first and second electrodes.

The rectifier may be provided inside the thermoelectric module.

The plurality of thermoelectric modules may be configured in a stack structure.

According to another exemplary embodiment of the present invention, there is provided an AC powered thermoelectric device, including: a first thermoelectric module; a second thermoelectric module connected to the first thermoelectric module in parallel; a first rectifier connected to the first thermoelectric module in series and controlling AC power having a first polarity to be applied to the first thermoelectric module; and a second rectifier connected to the second thermoelectric module in series and controlling AC power having a second polarity to be applied to the second thermoelectric module.

In this case, the first polarity may be any one of a positive pole and a negative pole, and the second polarity may be a polarity reverse to the first polarity.

The first and the second rectifiers may be connected to each other in parallel, having different polarities.

In addition, the first rectifier may be arranged in a sequence of anode-cathode, and the second rectifier may be arranged in a sequence of cathode-anode.

### BRIEF DESCRIPTION OF THE DRAWINGS

FIG. 1 is a configuration diagram of an AC powered thermoelectric device according to an exemplary embodiment of the present invention;

FIG. 2 is a detailed configuration diagram of a thermoelectric module of FIG. 1;

FIG. 3 is a graph showing one example of the AC power output from the power supplier of FIG. 1;

FIG. 4 is a configuration diagram showing another exemplary embodiment of the thermoelectric module of FIG. 1; and

FIG. 5 is a configuration diagram of an AC powered thermoelectric device according to another exemplary embodiment of the present invention.

### DESCRIPTION OF THE PREFERRED EMBODIMENTS

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

Hereinafter, exemplary embodiments of the present invention will now be described in detail with reference to the accompanying drawings.

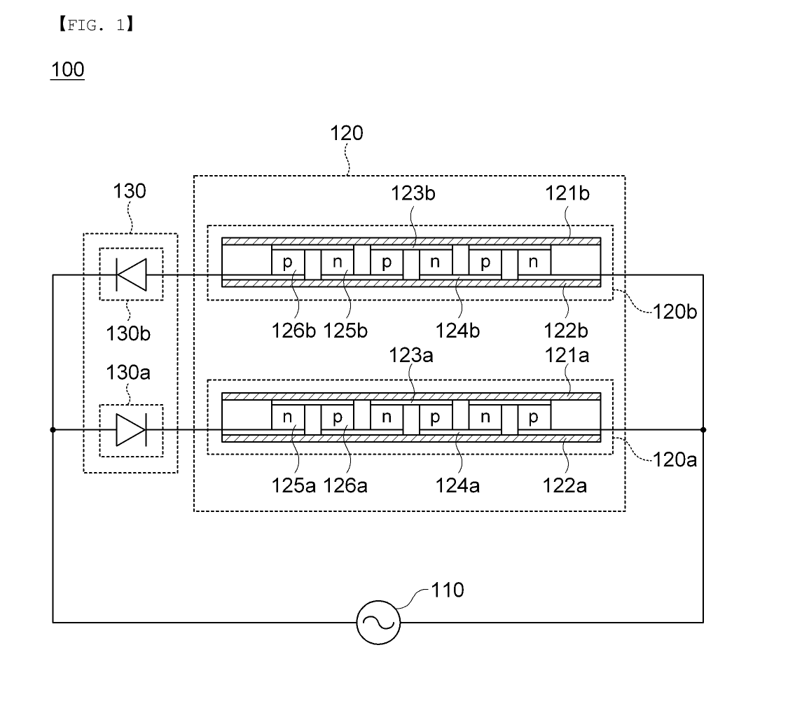

FIG. 1 is a configuration diagram of an AC powered thermoelectric device according to an exemplary embodiment of the present invention.

As shown in FIG. 1, the AC powered thermoelectric device 100 is configured to include a power supplier 110, a thermoelectric module 120, and a rectifier 130.

The power supplier 110, which is a unit outputting alternating current (AC) power, is configured as various shapes of power devices capable of outputting AC power.

The thermoelectric modules 120: 120a to 120n are formed in plural, wherein each thermoelectric module 120 includes first and second substrates 121 and 122, first and second electrodes 123 and 124 each disposed on the inner surface of the first and second substrates 121 and 122, and thermoelectric elements 125 and 126 provided between the first and second electrodes 123 and 124 to be bonded to the first and second electrodes 123 and 124.

Meanwhile, in the exemplary embodiment of the present invention, first and second thermoelectric modules 120a and 12b configured of two thermoelectric modules 120 will be described by way of example.

The first and second substrates 121 and 122 are spaced at a predetermined interval and disposed to be opposite to each other. The first and second substrates 121 and 122 may be made of an insulating ceramic material having excellent thermal conductivity.

The first and second electrodes 123 and 124 may include at least any one of Ag, Au, Pt, Sn, and Cu. In this case, the first and second electrodes 123 and 124 may be formed in a single layer structure of a single component and a multi-layer structure including at least two layers. Alternatively, the first and second electrodes 123 and 124 may be formed in a single layer structure with a mixture of at least two components.

The thermoelectric elements 125 and 126 are interposed between the first and second electrodes 123 and 124 and are bonded to the first and second electrodes 123 and 124. In this case, each of the first and second electrodes 123 and 124 is buried in the first and second substrates 121 and 122 and flatness of the first and second substrates 121 and 122 is maintained, such that the bonding stability between the thermoelectric elements 125 and 126 and the first and second electrodes 123 and 124 can be secured.

In addition, the electrical resistance and the thermal resistance can be lowered due to the bonding stability between the thermoelectric elements 125 and 126 and the first and second electrodes 123 and 124, such that the figure of merit of the thermoelectric module 120 can be increased.

The thermoelectric elements 125 and 126 are configured to include an N type semiconductor 125 and a P type semiconductor 126.

Herein, the N type semiconductor 125 and the P type semiconductor 126 may be alternately arranged on the same plane. At this time, a pair of N type semiconductor 125 and P type semiconductor 126 may be electrically connected by the first electrode 123 disposed at the upper surfaces thereof, and another pair of N type semiconductor 125 and P type semiconductor 126 next thereto may be electrically connected by the second electrode 124 disposed at the lower surfaces thereof.

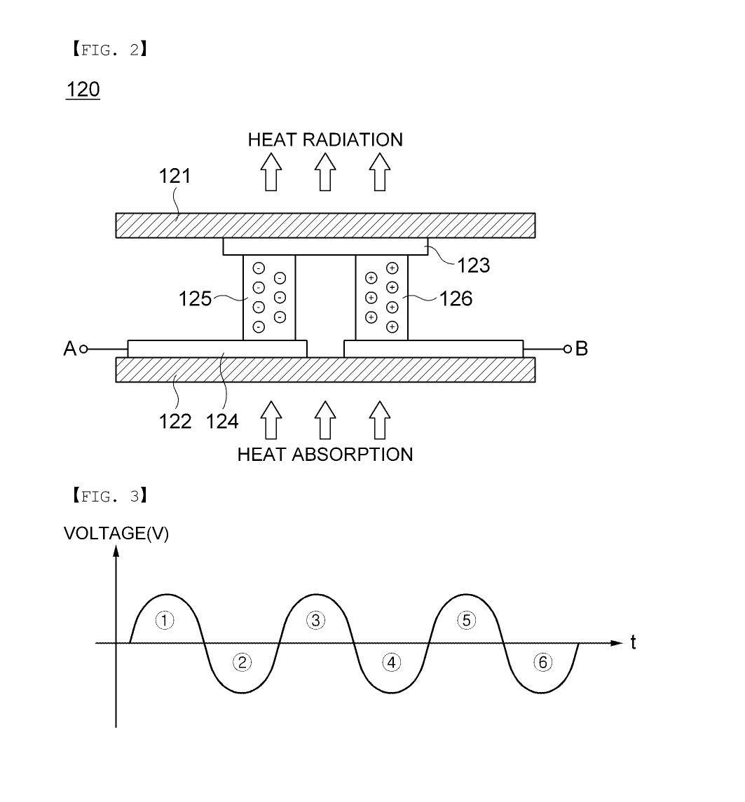

FIG. 2 is a detailed configuration view of the thermoelectric module of FIG. 1. As shown in FIG. 2, when power is applied to the thermoelectric module 120 through contact points of A and B, electrons (e−) and holes (h+), which are carriers, are generated from the electrode on one surface, such that the electrons flow through the N type semiconductor 125 and holes flow through the P type semiconductor 126, and as a result, heat and electricity are transferred.

The carriers are recombined on the electrode on the opposite surface and heat is absorbed at the second substrate 122 adjacent to the second electrode 124 in which the carriers are generated. In addition, heat is radiated at the first substrate 121 adjacent to the first electrode 123 in which the carriers are recombined. These portions are configured as a cold side and a hot side, respectively, thereby forming both surfaces of the thermoelectric module 120.

Meanwhile, the plurality of thermoelectric modules 120a and 120b are connected in parallel, having different polarities, that is, opposite polarities.

For example, the first thermoelectric module 120a may be configured such that the first thermoelectric elements may be arranged in the sequence of N type-P type-N type-P type-N type-P type semiconductors. The second thermoelectric module 120b may be configured such that the second thermoelectric elements may be arranged in the sequence of P type-N type-P type-N type-P type-N type semiconductors.

The reason for connecting the plurality of thermoelectric modules 120a to 120n with opposite polarities, is for driving the thermoelectric module with both poles of the AC power, as to be described below.

The rectifier 130 including 130a to 130n, which is a unit controlling AC power having different polarities to be applied to the plurality of thermoelectric modules 120a to 120n, may be configured of diodes.

The diodes are connected to each of the plurality of thermoelectric modules 120a to 120n in series, wherein the diodes are connected to each other in parallel, having different polarities.

FIG. 3 is a graph showing one example of the AC power output from the power supplier of FIG. 1. Referring to FIGS. 1 and 3, the first diode 130a is arranged on the first thermoelectric module 120a in a sequence of anode-cathode, and the second diode 130b is arranged in the second thermoelectric module 120b in a sequence of cathode-anode.

When power is applied, current flows from the anode terminal to the cathode terminal of the diode. Therefore, when positive AC power such as \textcircled{1}, \textcircled{3}, and \textcircled{5} in FIG. 3 is applied from the power supplier 110, the first thermoelectric module 120a is operated, and when negative AC power such as \textcircled{2}, \textcircled{4}, and \textcircled{6} in FIG. 3 is applied from the power supplier 110, the second thermoelectric module 120b is operated.

Electric current flows only in one direction in each of the thermoelectric module due to the configuration, such that the positions of the hot side and the cold side may be fixed.

Meanwhile, the configuration in which the diodes 130a to 130n are connected to each of the plurality of thermoelectric modules 120a to 120n in series may be applied to a case in which the AC powered thermoelectric device 100 is implemented using the plurality of thermoelectric modules 120a to 120n and may also be applied to a case in which one thermoelectric module 120 is implemented using the arrangement of the plurality of thermoelectric elements.

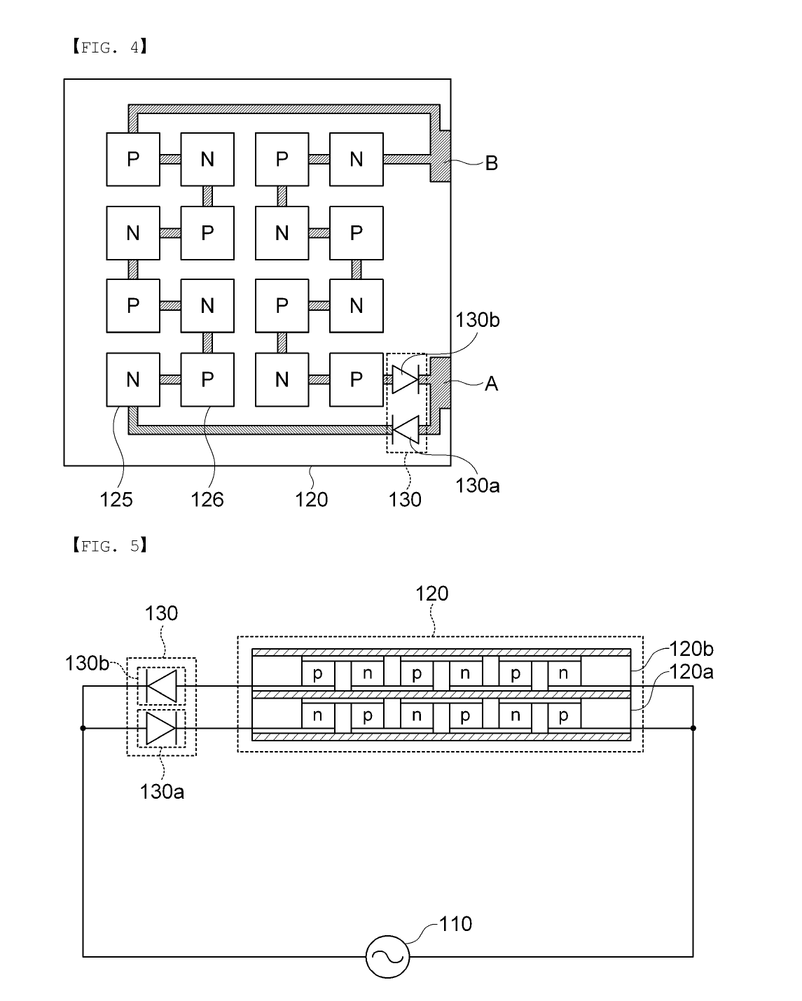

More specifically, FIG. 4 is a configuration diagram showing another exemplary embodiment of the thermoelectric device of FIG. 1. As shown in FIG. 4, it is possible to configure the thermoelectric module capable of completely and independently using AC power by embedding the first and second diodes 130a and 130b in the thermoelectric module 120.

In other words, the diode 130 in FIG. 1 is provided outside the thermoelectric module 120, but the diode 130 in FIG. 4 is provided inside the thermoelectric module 120.

FIG. 5 is a configuration diagram of an AC powered thermoelectric device according to another exemplary embodiment of the present invention. As shown in FIG. 5, the thermoelectric module 120 is configured in a stack structure in which the plurality of thermoelectric modules 120a to 120n are stacked. On the other hand, the AC powered thermoelectric device may be considered as one thermoelectric module 120 in which a plurality of thermoelectric elements are stacked.

For example, when the lower surface of the first thermoelectric module 120a is a hot side and the upper surface of the second thermoelectric module 120b is a cold side, the surface in contact with the first thermoelectric module 120a and the second thermoelectric module 120b is configured of a single substrate, such that the heating and cooling functions are not performed thereon. Therefore, the lower surface of the first thermoelectric module 120a performs the heating function and the upper surface of the second thermoelectric module 120b performs the cooling function.

As described above, when the thermoelectric module is configured in a stack structure in which the plurality of thermoelectric modules are stacked, an optimal value of electrical current may be found by controlling the electrical resistance of the thermoelectric module, thereby making it possible to improve performance of the thermoelectric device.

In conclusion, when positive AC power is applied in a structure in which the plurality of thermoelectric modules are connected in parallel, having opposite polarities, and the diodes having opposite polarities for each thermoelectric module are connected in series, some of the thermoelectric modules are operated, and when negative AC power is applied, the remainder of the thermoelectric modules are operated, respectively. Therefore, the AC power can be used as it is, without a converter converting AC power to DC power.

As described above, according to the thermoelectric device according to an exemplary embodiment of the present invention, the diodes having opposite polarities are connected to each of the plurality of thermoelectric modules, such that some of the thermoelectric modules are operated when positive AC power is applied and the remainder thereof are operated when negative AC power is applied, thereby making it possible to use both poles of the AC power.

In addition, since the AC power is used as it is, it is possible to simplify a power device, thereby allowing to make the thermoelectric device light and slim and reduce manufacturing cost.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A thermoelectric device, comprising:
a power supplier outputting AC power;
a plurality of thermoelectric modules; and
a plurality of rectifiers connected to each of the plurality of thermoelectric modules in series and applying the AC power having different polarities to each of the plurality of thermoelectric modules.

2. The thermoelectric device according to claim 1, wherein the plurality of rectifiers allow some of the plurality of thermoelectric modules to be operated when positive AC power is applied from the power supplier, and allows the remainder of the plurality of thermoelectric modules to be operated when negative AC power is applied from the power supplier.

3. The thermoelectric device according to claim 1, wherein the plurality of rectifiers are connected in parallel, having different polarities.

4. The thermoelectric device according to claim 1, wherein the rectifiers are diodes.

5. The thermoelectric device according to claim 1, wherein the plurality of thermoelectric modules are connected to each other in parallel.

6. The thermoelectric device according to claim 1, wherein each of the plurality of thermoelectric modules includes:
first and second substrates;
first and second electrodes each disposed on the inner surface of the first and second substrates; and
thermoelectric elements provided between the first and second electrodes to be bonded to the first and second electrodes.

7. The thermoelectric device according to claim 1, wherein the rectifier is provided inside the thermoelectric module.

8. The thermoelectric device according to claim 1, wherein the plurality of thermoelectric modules are configured in a stack structure.

9. A thermoelectric device, comprising:
a first thermoelectric module;
a second thermoelectric module connected to the first thermoelectric module in parallel;
a first rectifier connected to the first thermoelectric module in series and controlling AC power having a first polarity to be applied to the first thermoelectric module; and
a second rectifier connected to the second thermoelectric module in series and controlling AC power having a second polarity to be applied to the second thermoelectric module.

10. The thermoelectric device according to claim 9, wherein the first polarity is any one of a positive pole and a negative pole, and the second polarity is a polarity reverse to the first polarity.

11. The thermoelectric device according to claim 9, wherein the first and the second rectifiers are connected to each other in parallel, having different polarities.

12. The thermoelectric device according to claim 9, wherein the first rectifier is arranged in a sequence of anode-cathode, and
the second rectifier is arranged in a sequence of cathode-anode.
